(19) United States
(12) Patent Application Publication
(10) Pub. No.: US 2008/0285358 A1
(43) Pub. Date: Nov. 20, 2008

(54) Method and circuit for stressing upper level interconnects in semiconductor devices

(75) Inventor: Klaus Nierle, Essex Junction, VT (US)

Correspondence Address: POSZ LAW GROUP, PLC, 12040 SOUTH LAKES DRIVE, SUITE 101, RESTON, VA, 20191, US

(73) Assignee: Qimonda North America Corp., Cary, NC (US)

(21) Appl. No.: 11/798,513

(22) Filed: May 15, 2007

(51) Int. Cl. G11C 5/14; G11C 29/00; G11C 7/00

(52) U.S. Cl. 365/189.09; 365/201; 365/203

(57) ABSTRACT

A device or method for effectively stressing an interconnect in a current path of a semiconductor device. A bidirectional current is established across the current path, which stresses the interconnect therein.

### BACKGROUND

Defects and failures occur during the manufacture of semiconductor devices. A “failure” occurs when a semiconductor device fails to meet specifications. A “defect” occurs when a semiconductor device has an improper circuit structure that currently presents a failure of the device, or has the potential to cause failure during the expected lifetime of the device. Defects can occur in interconnects that are arranged between conductive layers within a semiconductor device. A defect in interconnects may not occur when the semiconductor device is produced, but such a defect has the potential to fail (e.g., short) during the expected lifetime of the semiconductor device.

During manufacture of semiconductor devices, voids are formed during the deposition of the necessary layers on a substrate, which include interconnects. As circuit density on semiconductor devices increases, the size of interconnects becomes smaller. A void in smaller interconnects is more likely to cause a short during the life expectancy of the semiconductor device. Such a short can cause an open circuit or a reduced voltage within the semiconductor device, and thus results in failure of the semiconductor device.

With the advent of Very Large Scale Integration (VLSI), many integrated circuit designs include several circuit functions on a single semiconductor substrate, such as memory storage and logic components for addressing and accessing the memory. In the case where a logic region and a dynamic random access memory (DRAM) are formed on the same substrate, the circuitry is commonly referred to as an embedded DRAM. In a DRAM, a plurality of conductor layers can be arranged above the actual memory cell array. One of these conductor layers can be connected to the WL-on potential and another connected to the WL drive circuit. Interconnects are arranged between these conductor layers, allowing the precharge of the WL-on potential to charge the word lines of the memory cells. Interconnects can also be used between the bit lines of DRAM.

Functional problems caused by voids in the upper level interconnects on DRAM containing semiconductor devices occur in certain instances at a very late state of the product life time and can not easily be detected or effectively stressed during semiconductor manufacturing. This is the case for the word line (WL) drive wiring, because the capacitive load of the WL is not large enough to establish a stress current which is sufficiently high to aggravate the marginality of the current path of the WL drive circuit.

Testing is performed on semiconductor devices to identify defects and failures. A conventional approach to testing interconnects involves operating the DRAM word line control in a nominal fashion while elevating the internal voltages by executing a series of word line activate-precharge sequences. However, this approach only has a very limited effect on marginal connections, such as interconnects. This past approach is not suitable for aggravating or stressing defective connections to a level that results in an open circuit or unacceptably reduced voltage that is easily detected during a following product testing.

### SUMMARY OF THE INVENTION

A device or method for effectively stressing an interconnect in a current path of a semiconductor device. A bidirectional current flow is established across the current path, which stresses the interconnect.

### BRIEF DESCRIPTION OF THE DRAWINGS

The accompanying figures, where like reference numerals refer to identical or functionally similar elements and which together with a detailed description set forth herein are incorporated in and form part of the specification, serve to further illustrate various exemplary embodiments and to explain various principles and advantages in accordance with this application.

FIG. 1 is a block diagram showing a test circuit on a semiconductor chip including a memory cell array and conductive layers with conductive interconnects extending between the conductive layers in accordance with an embodiment of this application.

FIG. 2A is a timing diagram showing a timing signal for an external control pin, such a clock signal, in accordance with an embodiment of this application.

FIG. 2B is a timing diagram showing a modified signal based on the signal shown in FIG. 3A in accordance with an embodiment of this application.

FIG. 2C is a diagram showing the change in voltage between two levels, A and B, over time that is output from the voltage generator in accordance with an embodiment of this application.

FIGS. 3A is a block diagram showing various components of the block diagram of FIG. 1 in more detail and identifying a typical stress path including an interconnect and current flow in a direction in accordance with an embodiment of this application.

FIG. 3B is a block diagram that is similar to that shown in FIGS. 3A and identifies a typical stress path including an interconnect and current flow in another direction in accordance with an embodiment of this application.

FIG. 4 is a flow diagram illustrating a procedure for stressing interconnects on a semiconductor chip in accordance with an embodiment of this application.

### DETAILED DESCRIPTION

The following exemplary embodiments and aspects thereof are described and illustrated in conjunction with structures and methods that are meant to be exemplary and illustrative, and not limiting in scope. In the following description, numerous specific details are set forth to provide a thorough understanding of the embodiments described in this application. In specific embodiments, circuits are shown in block diagram form in order not to obscure the embodiments described in this application in unnecessary detail. For the most part, details have been omitted inasmuch as such details are not necessary to obtain a complete understanding of the embodiments described in this application.

The embodiments of this application relate to a method and circuit for stressing interconnects formed between conductive layers in a semiconductor device. These embodiments include stressing interconnects contained within an array of dynamic random access memories (DRAMs), such as where interconnects that supply voltage to the word lines or bit lines of the memory array are arranged between conductive layers. These embodiments also include stressing interconnects arranged within any semiconductor device, such as those including logic components and memory storage devices other than DRAMs, for example, SDRAM (synchronous DRAM), SRAM (static random access memory), as well as stand alone RAM (random access memory). These embodiments further include stressing interconnects within VLSI devices where several circuit functions are provided on a single semiconductor substrate, such as memory storage and logic components for addressing and accessing the memory.

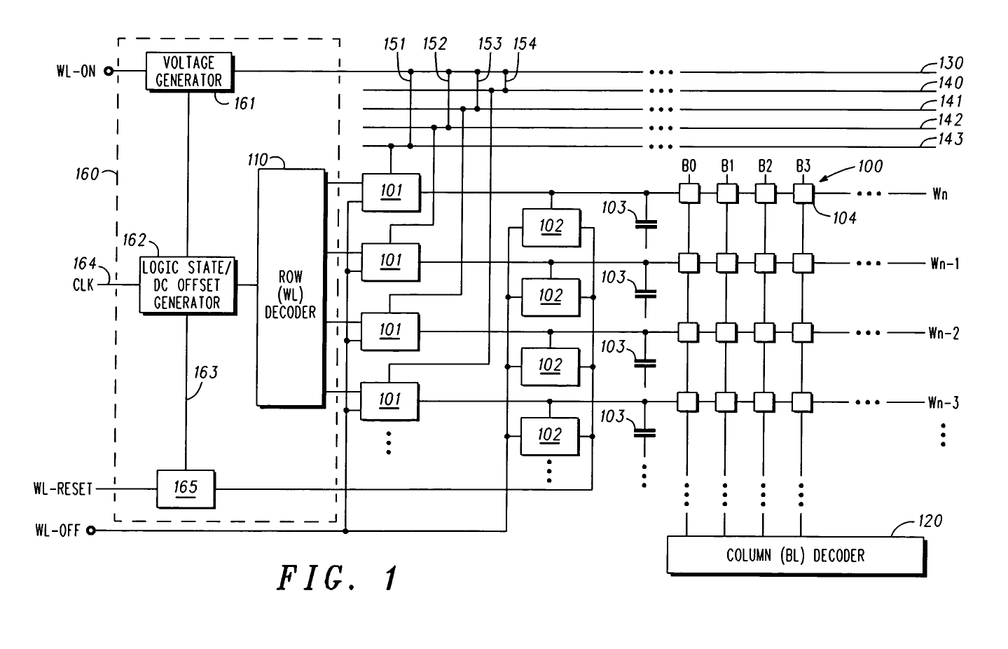

FIG. 1 represents a circuit diagram that includes a memory device 100, where a memory array is divided into word lines (WL) represented by horizontal lines and columns (or bit lines (BL)) represented by vertical lines. The word lines are identified by Wn, Wn-1, Wn-2 and Wn-3. The bit lines (BL) are identified by B0, B1, B2 and B3. Memory cells 104 are arranged at the intersection or crossover points of each of the word lines and bit lines. Only a few word lines, bit lines and memory cells are shown in FIG. 1, in order not to obscure the embodiments described in this application in unnecessary detail. While four word lines, four bit lines and 16 memory cells are shown, a larger number of word lines, bit lines and memory cells can be used, as understood by those skilled in the art, depending on the size and configuration of the memory array, as desired.

In the memory device 100 shown in FIG. 1, the memory cells 104 are selectively connected across the word lines Wn, Wn-1, Wn-2 and Wn-3 to WL on/off switches 101 and across the bit lines B0, B1, B2 and B3 to a column (BL) decoder 120. The WL on/off switches 101 are selectively connected to a word line-off (WL-off) potential (e.g., ground) and to a row (WL) decoder 110. In addition, the memory cells 104 are also selectively connected across the word lines Wn, Wn-1, Wn-2 and Wn-3 to the WL-off potential through WL reset switches 102. A word line capacitor (parasitic capacitor) 103 is arranged along each word line, such as between the memory cell 104 and the WL on/off switch 101. The WL on/off switches 101 are selectively connected across conductive layers 140, 141, 142 and 143 and interconnects 151, 152, 153 and 154 respectively to conductive layer 130, which in turn is connected to a word line-on (WL-on) potential through a voltage generator 161.

In the embodiment of FIG. 1, each word line is supplied by one conductive layer 140, 141, 142, or 143 associated with one interconnect 151, 152, 153 or 154 for illustration purposes only. Although not shown, one conductive layer (i.e., one of 140, 141, 142 or 143) and a corresponding interconnect (i.e., one of 151, 152, 153 or 154) is typically associated with a plurality of word lines, such as four or more word lines.

While five conductive layers 130 and 140-143 and four interconnects 151-153 are shown, a larger number of conductive layers and interconnects can be used, as understood by those skilled in the art, depending on the size and configuration of the memory array, logic chips, etc., as desired. The conductive layers and interconnects can be made of doped polysilicon, doped amorphous silicon, germanium silicon, titanium nitride, a metallic material (such as an AlCu alloy), composites thereof, or a like conductive material.

The circuit shown in FIG. 1 further includes a test circuit 160 that can be added to the regular WL control to establish the control of the WL-on voltage and/or WL reset devices via an external control pin (not shown). The test circuit 160 controls the stressing of interconnects through a stress path that includes a word line (WL) driver circuit, which can include, for example, the conductive layer 130, one of the conductive layers 141-143, one of the interconnect 151-154, and one of the WL on/off switches, one of the word lines (e.g., Wn) and one of the WL capacitors 103 associated with the word line (e.g., Wn). In addition, the test circuit 160 includes a voltage generator 161, a logic state/DC offset generator 162, and a WL-reset controller 165.

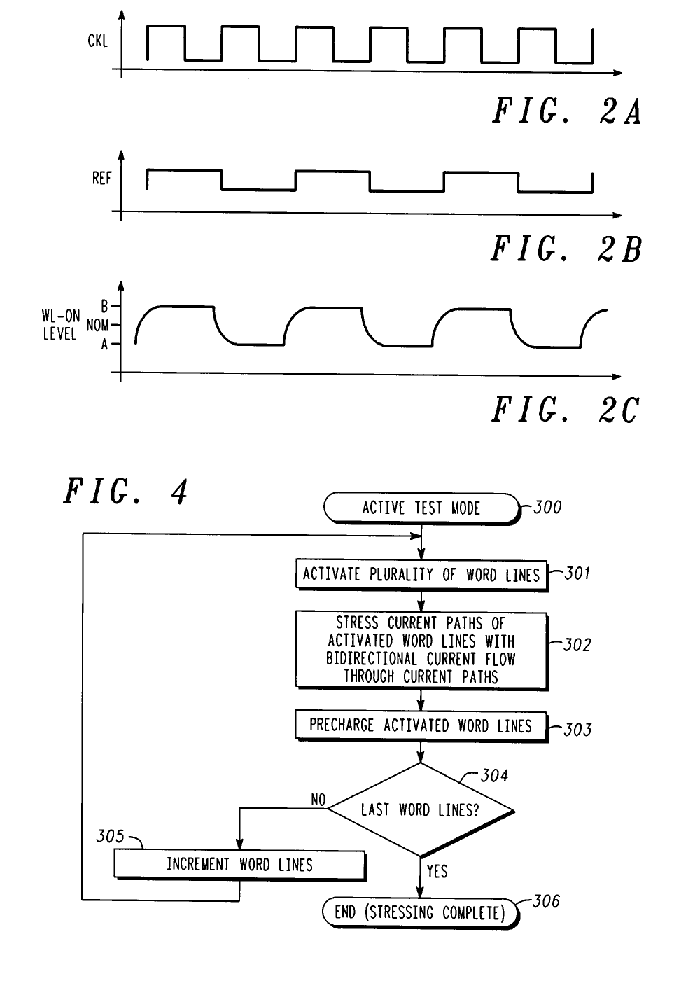

When enabled, the test circuit 160 allows control of the WL precharge device (such as WL reset switches 102) by utilizing an external pin (not shown). The enabling of the WL precharge device by the test circuit 160 is not coupled with a discontinued or intermittent operation of the WL activate device, but rather results in an alternating or bidirectional current flow between the WL voltage level (WL-on potential) and the WL capacitor 103 to establish a current path for stressing the interconnect lines in the WL drive circuit. At the same time, the logic state/direct current (DC) offset generator 162 modifies a command signal, such as the clock signal, shown in FIG. 2A. For example, the logic state/DC offset generator 162 can modify the clock signal by reducing its frequency, so as to output a reference voltage as shown in FIG. 2B.

The voltage generator 161 adjusts the WL-on potential in a manner and to a WL-on voltage level that avoids overstressing of the WL driver current path. For example, the voltage generator 161 or other similar device varies the WL-on potential from a nominal voltage (e.g., 2-4 V) to a test voltage between two values A and B, as shown in FIG. 2C, which respectively can be about 20 to 50% above and below the nominal voltage. The selected word lines are active while stressing the interconnect associated with the selected word lines. After stressing the interconnect, a simple precharge all command can deactivate all the selected word lines, which can be supplied by the logic state/direct current (DC) offset generator 162 or can alternatively be supplied by an external pin.

The logic state/DC offset generator 162 of the test circuit controls the voltage generator 161 for the WL-on voltage during test mode. Based on an external control pin, such as the clock pin, the WL-on potential is repeatedly and sequentially increased and decreased between two voltage potentials or levels, such as A and B shown in FIG. 2C. The varying of the WL-on potential between two voltage potentials can be achieved, for example, by adapting the clock signal. The clock signal is received by the logic state/DC offset generator 162 through pin 164. The frequency of the clock signal is sufficiently modified or reduced by the logic state/DC offset generator 162 to provide a time interval sufficient for dynamic response of the voltage (WL-on) generator 161. For example, the clock signal received by the logic state/DC offset generator 162 (as shown in FIG. 2A) is modified, such as by reducing its frequency and/or adding a direct current (DC) offset component thereto. The logic state/direct current (DC) offset generator 162 outputs a reference voltage (as shown in FIG. 2B) to the voltage generator 161. Based on the reference signal received, the voltage generator 161 outputs a varying WL-on potential (as shown in FIG. 2C).

The curved portions of the WL-on level in FIG. 2C identify the WL-on voltage transitions between the first voltage level (e.g. level A as shown in FIG. 2C) and the second voltage level (e.g. level B as shown in FIG. 2C). The bidirectional current flows through the current path in a first direction when the WL-on voltage transitions from the first voltage level (e.g. A) to the second voltage level (e.g. B) and the current flows through the current path in a second direction when the WL-on voltage transitions from the second voltage level (e.g. B) to the first voltage level (e.g. A). Thus, a bidirectional or alternating current flow is established along the current path and through the interconnect, thereby stressing the interconnect.

The logic state/DC offset generator 162 of the test circuit can provide the necessary address and control signals to the row (WL) decoder 110 to activate a plurality of word lines within the memory device 100. This includes sequentially or incrementally addressing and activating a group or plurality of word lines in a memory array.

The test mode can be activated by a test control signal, such as a chip select signal, received by the logic state/DC offset generator 162. The control signal can be associated with pins on the semiconductor device other than the precharge pin and pins associated with word line operations. For example, the control signal can be associated with the clock pin, address pins, or other suitable pins, such as certain command pins. When the test mode is enabled, the WL precharge device (such as WL reset switches 102) can be controlled utilizing an external pin control.

During test mode, the voltage generator 161 supplies the test voltage to the stress path for a period of time A, which is independent of normal word line functioning. The period of time A can be determined experimentally and can be arbitrarily adjusted to a time sufficient for stressing the interconnect, which can be one minute or longer. The period of time A is not coupled with timing limitations associated with normal read/write operations during test mode, such as the transitions that would occur once from an ACTIVATE command to the next PRECHARGE command with typically 5 additional clock cycles for DESELECT command and WRITE/READ commands (ACT-DES-DES-READ-DES-DES-PRE-DES-ACT- . . . ), meaning one complete cycle for 7 clock cycles. But rather, the period of time A for stressing the interconnect can include one complete cycle for each clock cycle, as shown in FIG. 2C, which can be adjusted to a period of time A sufficient for stressing the interconnect.

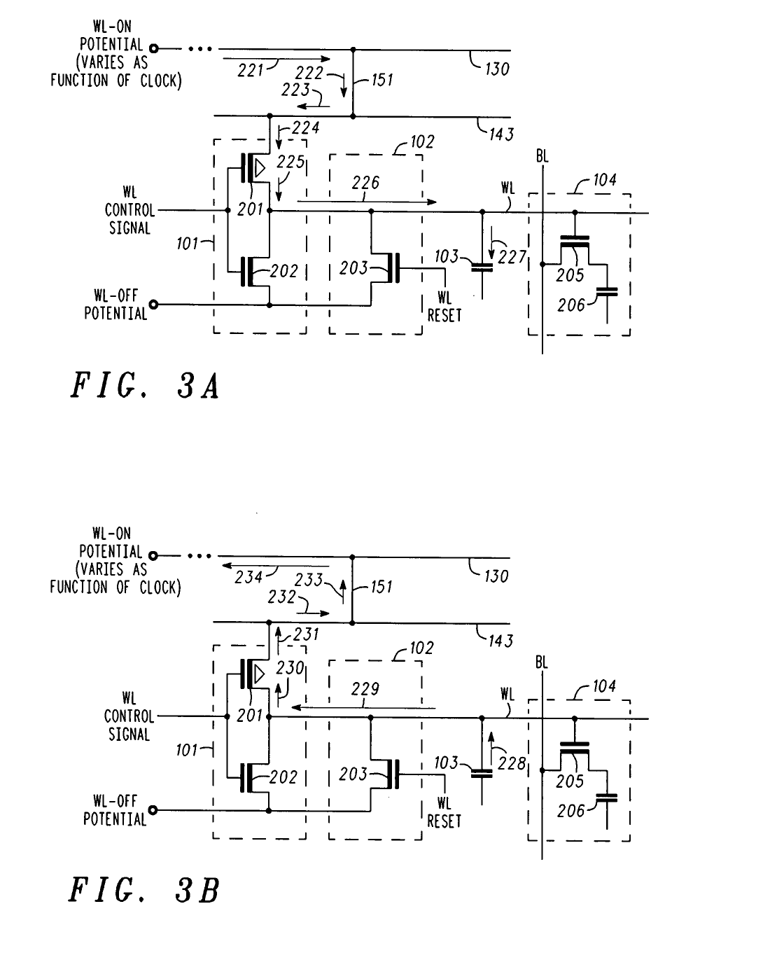

FIG. 3A includes a more detailed diagram of some of the components shown in FIG. 1. These include the WL on/off switches 101, the WL reset switch 102, the WL capacitor 103 and the memory cells 104. The WL on/off switches 101 can include p-channel MOSFET (PFET) 201 and an n-channel MOSFET (NFET) 202 or other transistors and switching devices. When a selected WL on/off switch 101 receives a WL control signal from the row (WL) controller 110, it activates the word line associated therewith. The WL reset switches 102 includes an NFET 203 or other transistor and switching device arranged between the word line and the WL-off potential. When WL reset switches 102 are reset by receiving a WL reset signal from the WL-reset controller 165 or elsewhere, all the word lines are reset or opened. The memory cell 104 includes an array transistor 205 and a capacitor 206, as understood in the art.

A representative stress (or stressing) path is shown in FIG. 3A by arrows 221-227. Arrow 221 represents the stress path from the WL-on potential (and voltage generator 161) along conductor 130, arrow 222 represents the current path across interconnect 151 and arrow 223 represents the current path along conductor 143. The stress path continues across the WL on/off switch 101, as shown by arrows 224 and 225, and along the word line, as shown by arrow 226. The stress path continues to and terminates at the WL capacitor 103, as shown by arrow 227. As mentioned above, the voltage generator 161 increases and decreases the WL-on potential from a nominal value used for normal word line operations (e.g., read/write) to a voltage level that will not harm the components of the semiconductor device along the stress path. When the WL-on potential, as varied by the voltage generator 161, is higher than the charge within the capacitor 103, the current flows in the direction of arrows 221-227 shown in FIG. 3A. In the embodiment shown in FIG. 3A, the components in the stress path in addition to the interconnect 151 include the WL on/off switch 101, such as a PFET 201 contained therein, and the WL capacitor 103.

The embodiment illustrated in FIG. 3B includes identical structures to those shown in 3A. A representative stress or current path includes that shown by arrows 228-234, which flows from the WL capacitor 103 through the WL driver circuit to the WL-on potential (and voltage generator 161). As shown in FIG. 3B, the stress path originates from the WL capacitor 103 continues along the word line, as shown by arrows 228 and 229. The stress path continues across the WL on/off switch 101, as shown by arrows 230 and 231. From the WL on/off switch 101, the stress path follows conductor 143 (arrow 232), interconnect 151 (arrow 233) and conductor 130 (arrow 234) to the voltage generator 161 (and WL-on potential). When the WL-on potential, as varied by the voltage generator 161, is lower than the charge within the capacitor 103, the current flows in the direction of arrows 228-234 shown in FIG. 3B. A stressing of the interconnect (i.e., 151) is performed by causing the current to flow from the WL-on potential towards the capacitor along the current path shown by arrows 221-227 in FIG. 3A, and then by causing the current to flow from the capacitor towards the WL-on potential along the current path shown by arrows 228-234 in FIG. 3B. This forward and backward, bidirectional or alternating current flow stresses the WL driver circuit and any interconnects contained therein.

While the current paths shown in FIGS. 3A and 3B are associated with a word line, those skilled in the art will understand that the arrangement shown in FIGS. 3A and 3B could be easily adapted to bit lines or other components that are powered by interconnects. A test circuitry for a bit line can include switches for activating bit lines, and switches for equaling or draining voltage on or from bit lines. An interconnect associated with a bit line can be stressed by varying the voltage potential supplied to the bit line between two voltage potential levels by adjusting a clock or other signal, along the same lines as discussed above for word lines. After the bit lines are activated, higher and lower voltage potentials can be alternatively apply to a capacitor or other charge storing device associated with the bit lines to establish a bidirectional current flow across the interconnects associated with the bit lines.

A method of stressing an interconnect according to one embodiment can be summarized as follows:
1. Activate test mode for control of WL-on voltage levels via external pin (not shown),
2. Activate a plurality of word lines (WLs),
3. Toggle signal from an external pin to stress current paths of activated word lines with bidirectional current flow through the current paths,
4. Apply an external precharge command selected or all WLs, and
5. Repeat steps 2 and 3 for additional and/or all other word lines.

FIG. 4 is a flow diagram illustrating an embodiment for stressing interconnects on a semiconductor chip. When the logic state/DC offset generator 162 receives the test control signal or other appropriate signal, the test mode is activated at 300. At 301, a plurality or multitude of word lines is activated. The word lines are activated in 301 by, for example, the logic state/DC offset generator 162 sending an appropriate signal to the row (WL) decoder 110. In 302, the WL-reset driver circuits including the interconnects are stressed by bidirectional current flow through the current paths. In this step, the control signal from an external pin, e.g., a clock pin 164, is toggled by the logic state/DC offset generator 162 modifying the control signal to a reference signal. The reference signal is used by a voltage generator 161 or other appropriate device to vary the WL-on voltage potential between two voltage levels. The varying of the WL-on voltage potential between two voltage levels causes a periodic and bidirectional current flow from the voltage generator 161 to the WL capacitor 103 and then from the WL capacitor 103 to the voltage generator 161. This procedure stresses the current path, such as that identified by arrows 221-227 in FIG. 3A and 228-234 in FIG. 3B.

In 303, after stressing the current paths including the interconnects for a period of time A, the activated word lines are precharged, such as by a command initiated by an external precharge command, the logic state/DC offset generator 162 to the WL-reset controller 165 together with other commands or other appropriate procedure. The WL-on potential is varied to acceptable voltages levels for stressing the interconnect, while not damaging other components in the current path. An acceptable voltage level is between two voltage levels, one above the nominal voltage and one below the nominal voltage. The period of time A for stressing the interconnect is one minute or longer and can be determined experimentally.

In 304, it is determined if the currently selected word lines are the last word lines to be stressed. If no, the word line addresses are incremented to the next plurality of word line addresses in 305. From 305, the method returns to 301 for activating the plurality of next word lines and stressing the paths associated with the plurality of next word lines including other or different interconnects. If the answer in 304 is yes (the stressing of the current paths of the last word lines were competed), the method proceeds to 306 and ends. In a typical stressing method, all the word lines in the memory array and be consecutively selected in groups, so that all the interconnects associated with all the word lines are stressed.

After the stressing of interconnects is complete, the semiconductor device can be tested by known methods to determine if any interconnects failed. For example, conventional testing of memory can be administered, where predetermined data or voltage values are applied to selected word line and bit line addresses, which correspond to certain memory cells to store or “write” data in the cells. Then, voltage values are read from such memory cells to determine if the data read matches the data written to those addresses. If the read data does not match the written data, then the memory cells at the selected addresses or interconnects associated therewith likely contain defects, and the semiconductor devices fail the test.

The foregoing description of the embodiments of the present invention is presented for purposes of illustration and description. It is not intended to be exhaustive or to limit the invention to the precise forms disclosed. Many variations and modifications of the embodiments described herein will be apparent to one of ordinary skill in the art in light of the above description. The scope of the invention is to be defined only by the claims appended hereto, as may be amended during the pendency of this application for patent, and all equivalents thereof.

Some embodiments can include a plurality of processes or steps, which can be performed in any order, unless expressly and necessarily limited to a particular order. As one of ordinary skill in the art would appreciate, other sequences of steps may be possible. Therefore, the particular order of the steps set forth in the specification should not be construed as limitations on the claims.

What is claimed is:

1. A semiconductor device comprising:
a current path including:
a first conductor layer;
a voltage generator connected to the first conductive layer;
a second conductor layer; and
an interconnect connecting the first and second conductive layers; and
a controller connected to the voltage generator,
wherein during test mode, the voltage generator, in response to a signal from the controller, varies the operating voltage between first and second voltage levels and stresses the interconnect in the current path by bidirectional current flow across the interconnect.

2. The semiconductor device according to claim 1, wherein the semiconductor device comprises a memory device and the first current path includes a word line that charges a memory cell.

3. The semiconductor device according to claim 2, wherein the word line includes a word line capacitor, and the bidirectional current flows between the voltage generator and the word line capacitor.

4. The semiconductor device according to claim 1, including a memory device, wherein the current path includes a bit line.

5. The semiconductor device according to claim 1, including a logic state/DC offset generator receiving a command signal, manipulating the command signal by adding a direct current (DC) offset component thereto, and feeding a resulting modified signal to the voltage generator.

6. The semiconductor device according to claim 5, wherein the command signal is a clock signal.

7. The semiconductor device according to claim 1, wherein the voltage generator varies the operating voltage between the first and second voltage levels as a function of an external clock signal and causes current to flow through the current path in a first direction during transition from the first voltage level to the second voltage level, and in a second direction during a transition from the second voltage level to the first voltage level.

8. A semiconductor device comprising:
a memory device including memory cells, word lines respectively connected to the memory cells, and word line (WL) driver circuits respectively connected to the word lines for activating the word lines in normal operations;
first conductor layers providing a nominal operating voltage for the word lines;
second conductor layers respectively connected to the WL driver circuits;
an interconnect connecting the first and second conductive layers and thereby supplying the operating voltage to the word lines; and
a test circuit generating a variable test voltage through the interconnect, the test circuit including a voltage generator periodically increasing and decreasing a WL-on voltage between a first level above a nominal operating voltage and a second level below the nominal operating voltage.

9. The semiconductor device according to claim 8, wherein the test circuit includes a logic state/DC offset generator that reduces the frequency of a clock signal received on an external pin and provides a reference signal based thereon, and the reference signal is fed to the voltage generator.

10. The semiconductor device according to claim 8, wherein the word lines respectively include a word line capacitor, thereby establishing a bidirectional current flow between the voltage generator and the word line capacitor in one direction when the WL-on voltage is higher than a charge in the word line capacitor and in an opposite direction when WL-on voltage is lower than the charge in the word line capacitor.

11. The semiconductor device according to claim 9, wherein the voltage generator, in response to the reference signal, varies the WL-on voltage so that current flows through the current path in a first direction when the WL-on voltage transitions from the first voltage level to the second voltage level, and so that the current flows through the current path in a second direction when the WL-on voltage transitions from the second voltage level to the first voltage level.

12. An on-chip test circuit for stressing an interconnect in a current path of a word line (WL) driver circuit in a dynamic random access memory device, comprising:
a direct current (DC) offset generator connected to an external pin and configured to generate a WL-on reference signal based on a signal received on an external pin; and
a voltage generator including an input for receiving the WL-on reference signal and generating a WL-on voltage that varies from a nominal value to test voltage values respectively above and below the nominal value in a periodic manner, thereby creating a bidirectional current flow across the interconnect through the WL driver circuit.

13. The on-chip test circuit of claim 12, wherein the signal is a clock signal.

14. The on-chip test circuit of claim 12, wherein;
the voltage generator varies the test voltage values between first and second voltage values, the first voltage level being above a nominal WL-on voltage and the second voltage level being lower than the nominal WL-on voltage, and
the voltage generator, in response to the WL-on reference signal, varies the WL-on voltage so that current flows through the current path in a first direction when the WL-on voltage transitions from the first voltage level to the second voltage level, and so that the current flows through the current path in a second direction when the WL-on voltage transitions from the second voltage level to the first voltage level.

15. The on-chip test circuit of claim 12, wherein the WL driver circuit includes a word line capacitor associated with a word line that charges and decharges based on a direction of the bidirectional current flow.

16. A method for stressing an interconnect within a current path in a semiconductor memory device, comprising:
activating a plurality of current paths containing a interconnect;
stressing the interconnect of the plurality of current paths with bidirectional current flow through the current paths; and
precharging the plurality of current paths.

17. The method for stressing an interconnect according to claim 16, wherein activating the plurality of current paths includes activating a plurality of word lines containing the plurality of current paths.

18. The method for stressing an interconnect according to claim 16, wherein activating the plurality of current paths includes activating a plurality of bit lines containing the plurality of current paths.

19. The method for stressing an interconnect according to claim 16, wherein the stressing is continued at least one minute.

20. The method for stressing an interconnect according to claim 16, wherein the bidirectional current flow includes periodically increasing a voltage potential of the plurality of current paths to a first level voltage above a nominal voltage for the current paths and decreasing the voltage potential of the plurality of current paths to a second voltage level below the nominal voltage for the plurality of current paths, and
the bidirectional current flows through the plurality of current paths in a first direction when the WL-on voltage transitions from the first voltage level to the second voltage level, and the bidirectional current flows through the plurality of current paths in a second direction when the WL-on voltage transitions from the second voltage level to the first voltage level.

21. An on-chip test circuit for stressing an interconnect in a current path of a semiconductor memory device, comprising:
path activating means for selectively activating the current path;
offset means for receiving a command signal from an external pin, modifying the frequency of the command signal and outputting a reference voltage signal;
voltage generator means for receiving the reference voltage signal and for generating a WL-on voltage that varies from a nominal value to test voltage values respectively above and below the nominal value in a periodic manner; and
precharging means for applying an external precharge to the selected current path.

22. The on-chip test circuit according to claim 21, wherein the path activating means activates a plurality of word lines.

23. The on-chip test circuit according to claim 21, wherein the path activating means activates a plurality of bit lines.

24. The on-chip test circuit according to claim 22, wherein each of the plurality of word lines includes a word line capacitor.

25. The on-chip test circuit according to claim 21, further including incrementing means for selecting another current path containing another interconnect.
